(19) United States
(12) Patent Application Publication
(10) Pub. No.: US 2009/0186194 A1
(43) Pub. Date: Jul. 23, 2009

(54) Batch Process for Coating Nanoscale Features and Devices Manufactured From Same

(75) Inventor: Robert W. Grant, Camden, ME (US)

Correspondence Address: GREENBERG TRAURIG, LLP, ONE INTERNATIONAL PLACE, 20th FL, ATTN: PATENT ADMINISTRATOR, BOSTON, MA, 02110, US

(73) Assignee: Nanoscale Components, Inc.

(21) Appl. No.: 12/110,063

(22) Filed: Apr. 25, 2008

Related U.S. Application Data
(60) Provisional application No. 60/926,913, filed on Apr. 30, 2007.

(51) Int. Cl. B32B 3/30; B32B 15/04; C23C 18/00; B05D 3/00; C23C 16/54

(52) U.S. Cl. 428/164; 428/161; 427/248.1; 427/255.7; 427/255.23; 118/722; 118/725; 977/781

(57) ABSTRACT

A process for coating of at least one conformal thin film simultaneously onto the surface of a plurality or batch of substrates having nanoscaled features is provided. The process involves exposing a batch of substrates to a supercritical fluid mixture in a controlled environment, and subsequently heating and cooling the substrate, in the presence of the supercritical fluid mixture, beyond a threshold temperature at which film growth can be enabled to initiate conformal thin film deposition on the surface of the substrate and within the nanoscaled features. The supercritical fluid mixture may be generated in a manner so as to maintain a necessary concentration level of the precursor material to permit sufficient thin film growth within the controlled environment. The supercritical fluid mixture may also be introduced into the controlled environment in a manner which minimizes precipitation or loss of solubility of the precursor material in the mixture. A system of thin film deposition of a batch of substrates is also provided.

### RELATED US APPLICATION(S)

The present application claims priority to U.S. Provisional Patent Application Ser. No. 60/926,913, filed Apr. 30, 2007, which application is hereby incorporated herein by reference.

### TECHNICAL FIELD

The present invention relates to methods for coating substantially conformal thin film layers onto substrates, and more particularly, onto substrates having nanoscale features, and relates to devices manufactured from such methods.

### BACKGROUND ART

New techniques in patterning and deposition have led the way in fulfilling Moore's Law (the historical increase in processor speed), as well as the trend toward lower cost via smaller feature sizes and denser circuitry. Over the history of Large Scale Integrated (LSI) circuits, transistor density has increased dramatically to the extent that as the scale of construction has been halved, the density of transistors has increased by four. In addition, as the density increases, power consumption and electrical current requirements have also increased. In order to isolate transistors from voltage fluctuations resulting from the increased current and lower voltage, measures have been taken, for instance, large (decoupling) capacitors have been designed to isolate the LSI from power supply fluctuations. However, many of the required capacitors (currently planar) have grown in size to a point that they can no longer fit onto the IC chip.

Historically, capacitors have been formed on substrates, or more specifically, Silicon wafers, by depositing and patterning thin films of dielectric material and covering the dielectric material with a thin metal film as an electrode. As integrated circuits continue to be made smaller and smaller, the size of the capacitors also need to shrink. However, as sizes shrink to the micron or sub-micron size, the needed capacitance sometimes cannot be achieved within the new small area.

Nevertheless, the Microelectronics and MEMS industry is dependent on the deposition of thin films, such as those made from metals, metal oxides, and organic compounds into very small spaces. The formation of capacitors, field effect transistors, interconnects, channels etc. are very important to the miniaturization of integrated circuits, MEMS and other nano-scale devices. Significant within the field of small substrates with channels are the uses of catalytic converters, synthesizers etc., where ultra-thin films or seed layers of materials are deposited for use.

To address this, one approach has been to increase the dielectric property of the insulator. This can been achieved with materials, such as oxides of Hafnium or Tantalum, etc. In particular, if multiple metal oxides, such as high-k dielectrics and metal electrodes can be deposited conformally onto a Silicon wafer, then the space requirements of capacitor structures can be easily reduced, saving hundreds of millions of dollars in production costs. For example, if a Barium Strontium Titanate (BST) dielectric can be effectively used instead of the now common SiO₂ dielectric, a 400 times capacitor area reduction can be achieved. However, although the relative dielectric strength of these materials can help reduce the feature size of the capacitor, such can limit, for instance, the compatibility of the new materials.

In particular, conformity and stoichiometry control can act as limiting factors for Chemical Vapor Deposition (CVD). CVD can be used to deposit a dielectric, conductive metal oxide or metal using the decomposition of, for instance, metalorganic precursors in a partial vacuum condition. Since deposition is dependent on precursor concentration arriving to a surface, different deposition rates can result in non-conformal or non-uniform deposition on a non-planar substrate having deep features. For example, in the case of BST deposition using CVD, each of three precursors must be deposited stoichiometrically. Since the three associated precursors have different decomposition temperatures, boiling points, and growth characteristics, maintaining stoichiometry and conformity in a non-planar substrate surface has proven to be difficult. “Bridging” may also occur, eventually closing off the deep feature in the substrate prior to complete coating (FIG. 1). In addition, a CVD deposited film can include up to about 10% atomic Carbon contamination, which can affect the effectiveness of the resulting capacitor.

Sputtering, on the other hand, is a “line of sight” technology, which can be severely limited in non-planar architecture. In particular, droplets of metal are caused to travel across a high vacuum space from a source target toward a substrate. Momentum does not allow the droplets to turn or diffuse into the sides of a deep feature. As a result, this can leave a coating that essentially excludes the sides of the deep feature (FIG. 2). Moreover, if several metals are present in the sputtering target source, there are additional problems related to fractional distillation that can cause incorrect stoichiometry in the deep feature. A resulting film, therefore, may not perform properly.

In the case of Atomic Layer Deposition (ALD), growth rates can be exceedingly slow and carbon contamination, similar to CVD, may become an issue, even after an Oxygen annealing process. Moreover, with ALD, the precursor is decomposed in Oxygen at reduced pressure to deposit only one atomic monolayer at a time. This process, therefore, can be extremely slow for applications where hundreds of layers are needed, such as the case when depositing film thickness of, for example, 600 Angstroms and only 0.4 Angstroms (i.e., the thickness of a monolayer) can be deposited at a time. Therefore, even if ALD can provide a substantially conformal deposition method, and precursors were available for metal deposition, it would not address the speed requirements needed.

Supercritical CO₂ (SCCO₂) processing, such as that described in U.S. Pat. No. 5,789,027, U.S. Pat. No. 6,689,700, and U.S. Pat. No. 6,992,018, has demonstrated acceptable conformal film deposition. To date, SCCO₂ has been employed to dissolve and transport organometalics and other precursors to a reactor for thin film deposition. These SCCO₂ reactors, in general, have been designed to provide “cold wall” or “hot wall”, while the deposition process involved has relied on isothermal conditions for the reactor walls and/or fixed higher temperatures for the substrate(s). It should be noted that since supercritical gas creates solubility toward precursors in direct proportion to density, any pressure drop in the system can create precipitation that is undesirable. In particular, with present SCCO₂ environment, the precursor is generally introduced through a pressure drop (e.g. by way of a mixer or turbulator), and since solubility is density/pressure dependent, precipitation can occur upon introduction into the reactor. To that end, extra time must be given to re-dissolve the precursor. In many instances, even with the extra time, the precursor cannot be re-dissolved. As a result, thin film formation on the substrate can include surface defects.

In addition, with current SCCO₂ techniques, film thickness is controlled by the amount of precursor introduced. As such, essentially all of the precursor must be reacted. The need to have all of the precursor reacted can increase processing time, especially in view of smaller and smaller precursor concentrations that remain toward the end of the process. It should be noted that even though the growth rate of the film can be zero order above a few percent concentration, non-uniformities can be induced once the concentrations falls below this amount. Moreover, as the volume of chemical precursor must be finely measured to achieve repetitive film growth, the need to finely measure can represent additional cost to the process, as well as a source of error. Furthermore, in order to introduce a reagent, such as H₂, O₂ etc., to a reactor containing SCCO₂ or other dense gases, a significant amount of pressure, for example, thousands of pounds per square inch, must be applied requiring the use of expensive equipment (e.g., a compressor, a pump or a high-pressure cylinder). The need for expensive equipment can further add to the cost of operation, if not to safety concerns.

Accordingly, it would be desirable to provide a method for thin film deposition that can be done efficiently and cost effectively, that can minimize the amount of surface defects, and that can control formation of substantially uniform and conformal film layers and thickness.

### SUMMARY OF THE INVENTION

The present invention provides, in one embodiment, a process for providing a substantially conformal film (i.e., coating) onto surfaces of a plurality of substrates having nanoscale features.

In accordance with an embodiment, the method includes providing, within a controlled environment, a plurality of substrates, each having at least one nanoscaled feature extending into the substrate. Next, a mixture of a supercritical gas and a precursor material and a reagent gas or solvent may be introduced into the controlled environment in a manner which minimizes precipitation or loss of solubility of the precursor material in the mixture. In one embodiment, the mixture may be a non-reactive mixture of supercritical gas and a precursor material. Thereafter, the plurality of substrates may be simultaneously heated to a threshold temperature at which film growth can be enabled on the surface and along the nanoscaled feature of each substrate. Upon heating of the substrates to above the threshold temperature in the presence of the mixture, a substantially conformal thin film may be deposited on to the surface and along the nanoscaled feature of each substrate. In an embodiment, the mixture may be recirculated to maintain a necessary concentration level of the precursor material to permit sufficient thin film growth within the controlled environment. A concentration of about 0.2% by weigh of the precursor material within the controlled environment may be necessary to permit sufficient film growth. Subsequently, the substrate can be cooled to a temperature at which film growth can be terminated upon reaching a predetermined thickness.

In accordance with another embodiment of the present invention, a system for coating a batch of substrate is provided. The system, in an embodiment, includes a pathway along which a mixture of a supercritical gas and a precursor material can be directed. The pathway, in one embodiment, may be provided with a pre-reaction loop along which the mixture may be generated prior to the coating process. The system also includes a reactor, in fluid communication with the pathway, and within which a batch of substrates can be placed for thin film deposition. A pump may also be provided for recirculating the supercritical fluid mixture along the pathway, so as to facilitate and enhance solubility of the precursor material in the mixture. In an embodiment, a vessel may be situated in fluid communication with the pre-reaction loop of the pathway to provide additional volume within which the supercritical gas and precursor material can sufficiently mix. By allowing the supercritical gas and the precursor material to mix within the vessel, a minimum precursor concentration in solution may be generated in order to promote sufficient thin film deposition once the supercritical fluid mixture is circulated into the reactor.

The present invention further provides a coated substrate which can be manufactured utilizing a method of the present invention. The substrate includes at least one nanoscaled feature of substantially high aspect ratio of depth to width. In an embodiment, the high aspect ratio ranges from about 5:1 to about 100:1 depth to width. The substrate also includes a conformal thin film layer deposited substantially uniformly across a surface of the substrate and along all exposed surfaces of the nanoscaled feature. The thin film layer, in one embodiment, may be formed from a supercritical gas and a precursor material. In an embodiment, the layer may be a metal or metal oxide. The substrate further includes a conformal barrier layer deposited atop the thin film layer to protect the thin film layer against oxide reduction. If desired, the substrate may be provided with a second conformal thin film layer atop the initial conformal thin film layer. The second layer may be formed from a mixture of a supercritical gas and a second precursor material, which may be similar or different from the precursor material in the initial layer.

The present invention also provides a reactor for supercritical fluid deposition. The reactor includes, in one embodiment, a body portion within which a batch of substrates can be positioned for simultaneous thin film deposition. The reactor also includes a lid portion for complementarily engaging the body portion, so as to provide a substantially airtight fit therewith in the presence of supercritical pressure. A cassette may be provided for placement within a chamber of body portion and for accommodating a batch of substrates. The reactor further includes an inlet to introduce a supercritical fluid mixture into the reactor for subsequent thin film deposition on to a surface of each substrate in the batch. A heating element may be coupled to the body portion of the reactor for raising temperature of the batch of substrates to a threshold temperature at which film growth can be enabled on the surface of each substrate.

### BRIEF DESCRIPTION OF DRAWINGS

FIG. 1 illustrates a substrate coated with conventional Chemical Vapor Deposition.

FIG. 2 illustrates a substrate coated with convention Sputtering techniques.

FIG. 3 shows a graph with an illustrative threshold reaction temperature in connection with a deposition process of the present invention.

FIG. 4 illustrates an exemplary film growth rate in connection with a deposition process of the present invention.

FIG. 5 illustrates a system for Chemical Fluid Deposition in accordance with an embodiment of the present invention.

FIG. 6 illustrates a batch reactor for use in connection with the systems shown in FIG. 5.

FIGS. 7A-B and 8 illustrate various substrates coated in accordance with deposition processes of the present invention.

FIG. 9 is a graph illustrating the range along which capacitance density may be increased in connection with a capacitor fabricated in accordance with on embodiment of the present invention.

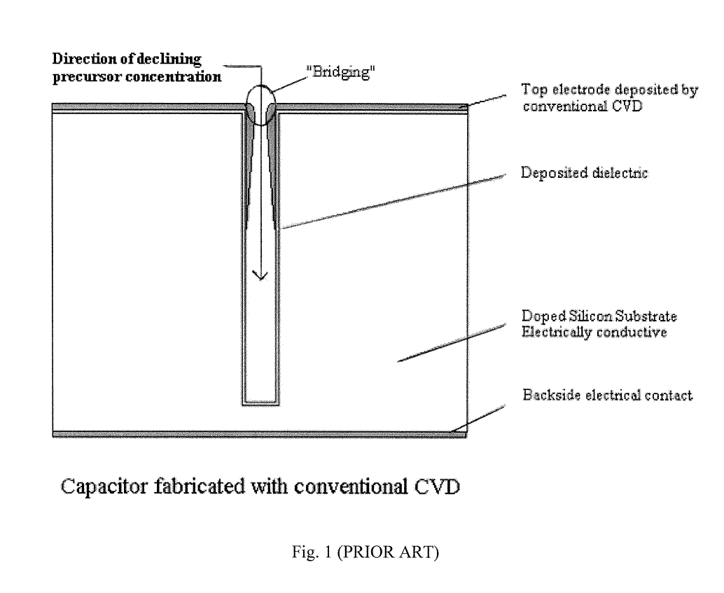

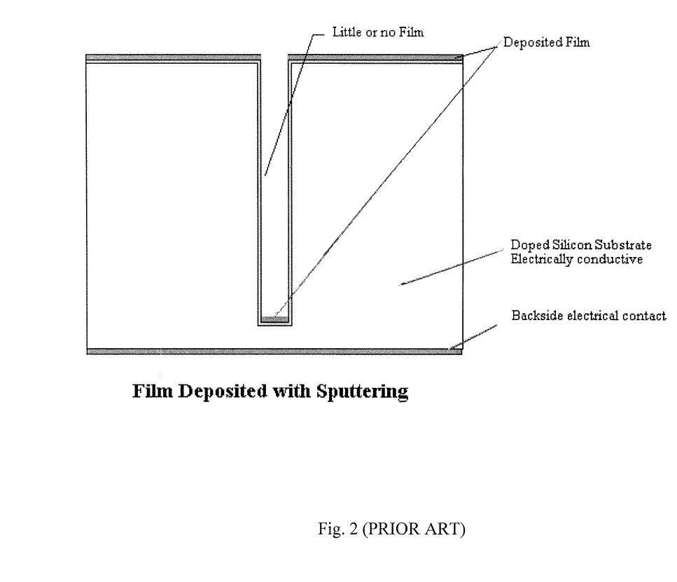

### DESCRIPTION OF SPECIFIC EMBODIMENTS

The present invention provides, in one embodiment, a process for coating of at least one conformal thin film simultaneously onto the surface of a plurality or batch of substrates having nanoscaled features. The process involves exposing a batch of substrates to a supercritical fluid mixture, and subsequently heating and cooling the substrate, in the presence of the supercritical fluid mixture, beyond a threshold temperature at which film growth can be enabled to initiate conformal thin film deposition on the surface of the substrate and within the nanoscaled features.

In accordance with one embodiment of the present invention, the supercritical fluid mixture includes a supercritical gas (i.e., a solvent), at least one precursor, such as an organo-metallo material for subsequent deposition onto the substrate, along with or in the absence of a reagent, such as H₂. Prior to introduction into the reaction, the supercritical gas source and the reagent gas source, in an embodiment, may be compressed up to supercritical pressure together, even though the reagent gas may not necessarily be in supercritical condition. The precursor may be introduced into the solution of supercritical gas and reagent gas to form the supercritical fluid mixture. In an embodiment the supercritical fluid mixture may be a non-reactive mixture. The precursor material may then be allowed to fully dissolve in the supercritical fluid mixture in advance of introduction to the reactor. Upon and during deposition, the mixture, in an embodiment, may be introduced in a way as not to cause precipitation or loss of solubility due to temperature or pressure changes. To accomplish this, as an example, since it is known that a precursor of Copper (Cu(tmhd)₂) can remain dissolved in solution of SCCO₂ at about 2500 PSI, and at about 40 degrees Centigrade, if the pressure is gradually reduced, while maintaining substrate temperature, at some point precipitation will take place. This lower pressure limit, at which precipitation occurs, can be determined with a supercritical gas solubility cell, such as that made by Supercritical Fluid Technologies, Newark, Del., 19711, 302-738-3420. The deposition process can then be carried out within a reactor above this pressure, so as to minimize or prevent precipitation.

To initiate thin film deposition, in an embodiment, the temperature and pressure within the reactor may be maintained at near or above supercritical condition, which pressure and temperature may be the same as that of the mixture being introduced. This can be achieved, in one embodiment, by filling the reactor with a supercritical gas at the necessary temperature and pressure to condition the reactor for deposition. Thereafter, a supercritical fluid mixture containing a supercritical gas, and at least one precursor in the presence or absence of a reagent, may be introduced into the reactor. In certain instances, additional gases, precursors, or reagents may be included in the supercritical fluid mixture if necessary. The introduction of the supercritical fluid mixture into the reactor, in an embodiment, can be at a temperature and pressure condition that fully supports the precursor in solution, but does not allow a significant chemical reaction to take place. Significant, as used herein means a reaction that allows a precipitation or film growth to take place. However, in certain instances, intermediate forms of the mixture are allowable, so long as they do not destroy the film growing capability of the mixture when the substrates are later heated to a reaction temperature. The introduction of the supercritical fluid mixture into the reactor can also be used to flush the conditioning supercritical gas from within the reactor. It should be appreciated that a volume of the supercritical fluid mixture, in one embodiment, may be generated outside of the reactor for use with each deposition sequence. If necessary, additional volumes may thereafter be generated for subsequent deposition sequences.

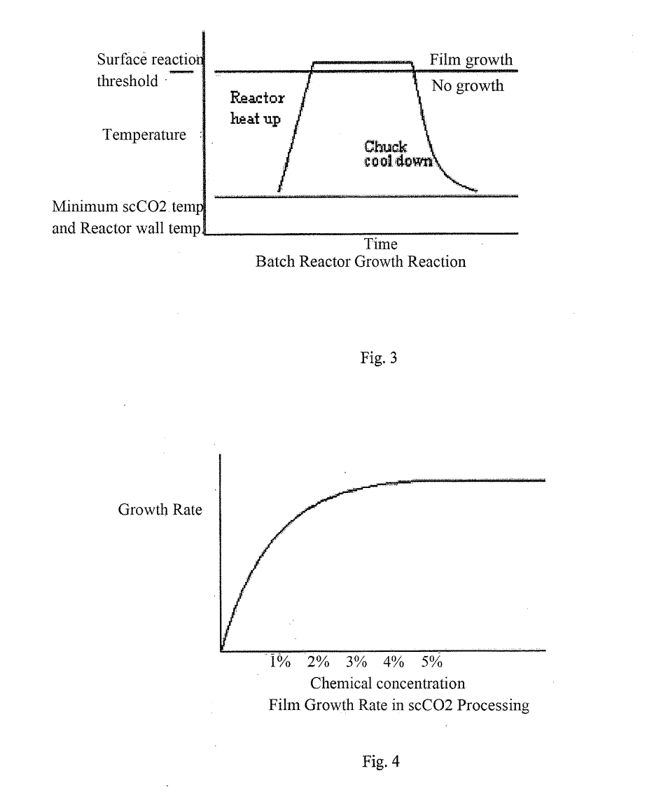

After the supercritical fluid mixture is introduced into the reactor, conformal film growth can be initiated by rapidly heating the reactor body (i.e., walls), so as to increase the temperature of the substrates upon which thin film growth is to occur. As shown in FIG. 3, the substrates, in an embodiment, may be heated to a desired threshold reaction temperature. Threshold reaction temperatures may typically be below 400° C., but can be dependent on the components of the supercritical fluid mixture. In an embodiment of the present invention, the threshold reaction temperature may be below 40° C.

Since film growth proceeds appreciably when the temperature of the substrate exceeds the threshold reaction temperature, film thickness can be controlled substantially accurately by time and temperature. It should be appreciated that since the dependence of film growth rate on concentration is generally known to be zero order above a few tenths of a percent concentration, as shown in FIG. 4, the amount of precursor material present during reaction may not be that important, even if the amount fluctuates, in order to achieve substantially uniform and conformal deposition. As such, so long as the concentration is maintained above a few percent, the film growth rate can be substantially constant, predictable and uniform. Moreover, in light of this, even if less than 100 percent of the conditioning supercritical gas is flushed out upon introduction of the supercritical fluid mixture, the presence of the conditioning supercritical gas may not affect the growth rate or deposition process.

Once the desired thickness is reached, to stop the film growth process, the temperature of the substrate may be allowed to drop below the threshold reaction temperature (i.e., the no reaction point), thereby effectively stopping the growth reaction. At the end of the deposition process, remaining reactants and byproducts can be purged away by flushing the reactor with additional pure supercritical gas.

The conformal thin film deposited by the process of the present invention can be used to coat within nanoscaled or deep features of a substrate, for instance, those features for in connection with capacitors, interconnects, conductive channels, cantilever beams etc. To the extent desired, multiple coatings of the same material may be deposited until the features on the substrate becomes substantially solid with little or no spacing or voids. Alternatively, a different precursor material may be used to deposit a different conformal thin film on top of the first conformal thin film.

A more detailed description of the process and system employed by the present invention is provided below.

### Chemical Fluid Deposition

Thin film layers to be formed in accordance with an embodiment of the present invention may initially be deposited onto a substrate using various well known approaches, such as Chemical Vapor Deposition, Atomic Layer Deposition, or Sputtering. In accordance with an embodiment of the present invention, a Chemical Fluid Deposition (CFD) process is used to obtain discrete conformal thin films or layers on a substrate having nanoscaled features.

In general, CFD is a process by which materials (e.g., metals, metal oxides, or organics) may be deposited from a supercritical or near-supercritical solution via chemical reaction of soluble precursors. CFD is generally described in detail in U.S. Pat. No. 5,789,027, which patent is hereby incorporated herein by reference. Desired materials can be deposited on a substrate, such as a silicon wafer, as a high-purity (e.g., better than 99%) thin film (e.g., less than 5 microns). The supercritical fluid employed may be used to transport a precursor material to the substrate surface where a reaction takes place, and to subsequently transport ligand-derived decomposition products away from the substrate to remove potential film impurities. Typically, the precursor in CFD is non-reactive by itself, and a reaction reagent (e.g., a reducing or oxidizing agent) may be mixed into the supercritical solution to initiate the reaction which forms the desired materials. The entire process takes place in solution under supercritical conditions. The process provides a high-purity film at various process temperatures under 250° C., depending on the precursors, solvents, and process pressure used.

### Solvents

Solvents that can be used as supercritical fluids are well known in the art and are sometimes referred to as dense gases (Sonntag et al., Introduction to Thermodynamics, Classical and Statistical, 2nd ed., John Wiley & Sons, 1982, p. 40). At temperatures and pressures above certain values for a particular substance (defined as the critical temperature and critical pressure, respectively), saturated liquid and saturated vapor states are identical and the substance is referred to as a supercritical fluid. Solvents that are supercritical fluids are less viscous than liquid solvents by one to two orders of magnitude. In CFD, the low viscosity of the supercritical solvent facilitates improved transport (relative to liquid solvents) of reagent to, and decomposition products away, from the incipient film. It should be noted that many reagents which would be useful in chemical vapor deposition are insoluble or only slightly soluble in various liquids and gases and thus cannot be used in standard CVD. However, the same reagents often exhibit increased solubility in supercritical solvents. Generally, a supercritical solvent can be composed of a single solvent or a mixture of solvents, including for example, a small amount (<5 mol %) of a polar liquid co-solvent such as methanol.

It is important that the reagents are sufficiently soluble in the super-critical solvent to allow homogeneous transport of the reagents. Solubility in a supercritical solvent is generally proportional to the density of the supercritical solvent. Ideal conditions for CFD include a supercritical solvent density of at least 0.2 g/cm³ or a density that is at least one third of the critical density (the density of the fluid at the critical temperature and critical pressure).

The table below lists some examples of solvents along with their respective critical properties. These solvents can be used by themselves or in conjunction with one another or other solvents to form the supercritical solvent in CFD. The table respectively lists the critical temperature, critical pressure, critical volume, molecular weight, and critical density for each of the solvents.

Critical Properties of Selected Solvents

| | T_{c} | p_{c} | V_{c} | Molecular | ρ_{c} |
|---|---|---|---|---|---|
| Solvent | (K) | (atm) | (cm/mol) | Wt. | (g/cm³) |
| CO₂ | 304.2 | 72.8 | 94.0 | 44.01 | 0.47 |
| C₂H₆ | 305.4 | 48.2 | 148 | 30.07 | 0.20 |
| C₃H₈ | 369.8 | 41.9 | 203 | 44.10 | 0.22 |
| n-C₄H₁₀ | 425.2 | 37.5 | 255 | 58.12 | 0.23 |
| n-C₅H₁₂ | 469.6 | 33.3 | 304 | 72.15 | 0.24 |
| CH₃—O—CH₃ | 400 | 53.0 | 178 | 46.07 | 0.26 |
| CH₃CH₂OH | 516.2 | 63.0 | 167 | 46.07 | 0.28 |
| H₂O | 647.3 | 12.8 | 65.0 | 18.02 | 0.33 |
| C₂F₆ | 292.8 | 30.4 | 22.4 | 138.01 | 0.61 |

Carbon dioxide (CO₂) is a particularly good choice of solvent for CFD. Its critical temperature (31.1° C.) is close to ambient temperature and thus allows the use of moderate process temperatures (<80° C.). It is also unreactive with most precursors used in CVD and is an ideal media for running reactions between gases and soluble liquids or solid substrates. Other suitable solvents include, for example, ethane or propane, which may be more suitable than CO₂ in certain situations, e.g., when using precursors which can react with CO₂, such as complexes of low-valent metals containing strong electron-donating ligands (e.g., phospines).

### Precursors, Reagents and Reaction Mechanisms

Precursors may be chosen so that they yield the desired material on the substrate surface following reaction with the reaction reagent. Materials can include metals (e.g., Cu, Ru, Rh, Pt, Ni, Pd, Ag, Au, Ti, CuAl, CuAlSi etc.), elemental semiconductors (e.g., Si, Ge, and C), compound semiconductors (e.g., III-V semiconductors such as GaAs and InP, II-VI semiconductors such as CdS, and IV-VI semiconductors such as PbS), oxides (e.g., SiO₂ and TiO₂), or mixed metal or mixed metal oxides (e.g., a superconducting mixture such as Y—Ba—Cu—O). Organometallic compounds and metallo-organic complexes are an important source of metal-containing reagents and are particularly useful as precursors for CFD. In contrast, most inorganic metal-containing salts are ionic and relatively insoluble, even in supercritical fluids that include polar modifiers such as methanol.

Some examples of useful precursors for CFD include metallo-organic complexes containing the following classes of ligands: beta-diketonates (e.g., Cu(hfac)₂ or Pd(hfac)₂, where hfac is an abbreviation for 1,1,1,5,5,5-hexafluoroacetylacetonate), alkyls (e.g., Zn(ethyl)₂ or dimethylcyclooctadiene platinum (CODPtMe₂)), allyls (e.g. bis(allyl)zinc or W(π⁴-allyl)₄), dienes (e.g., CODPtMe₂), or metallocenes (e.g., Ti(π⁵-C₅H₅)₂ or Ni(π⁵-C₅H₅)₂). For a list of additional potential precursors see, for example, M. J. Hampden-Smith and T. T. Kodas, Chem. Vap. Deposition, 1:8 (1995).

It should be noted that precursor selection for CVD is limited to stable organometallic compounds that exhibit high vapor pressure at temperatures below their thermal decomposition temperature. This limits the number of potential precursors. On the other hand, CFD obviates the requirement of precursor volatility, and instead replaces it with a much less demanding requirement of precursor solubility in a supercritical fluid.

Any reaction yielding the desired material from the precursor can be used in CFD. However, low process temperatures (e.g., less than 250° C., 200° C., 150° C., 1000 C, or 50° C.) and relatively high fluid densities (e.g., greater than 0.2 g/cm³) in the vicinity of the substrate are important features of CFD. If the substrate temperature is too high, the density of the fluid in the vicinity of the substrate approaches the density of a gas, and the benefits of the solution-based process may be lost. In addition, a high substrate temperature can promote deleterious fragmentation and other side-reactions that lead to film contamination. Therefore a reaction reagent, rather than thermal activation, may be used in CFD to initiate the reaction that yields the desired material from the precursor.

Some examples of useful reagents include, reducing agents such as H₂ or H₂S for reactions involving reduction of the precursor, oxidizing agents such as O₂ or N₂O for reactions involving oxidation of the precursor, hydrolizing agents such as H₂O for hydrolysis of the precursor. Other useful reagents can include an alcohol, an acid or a base. An example of an oxidation reaction in CFD is the use of O₂ (the reaction reagent) to oxidize a zirconium beta-diketonate (the precursor) to produce a metal thin film of ZrO₂. An example of a hydrolysis reaction in CFD is water (the reaction reagent) reacting with a metal alkoxide (the precursor), such as titanium tetraisopropoxide (TTIP), to produce a metal oxide thin film, such as TiO₂. The reaction can also be initiated by optical radiation (e.g., photolysis by ultraviolet light). In this case, photons from the optical radiation can be the reaction reagent.

In certain instances, chemical selectivity at the substrate can be enhanced by a temperature gradient established between the substrate and the supercritical solution. For example, a gradient of 40° C. to 250° C. or 80° C. to 150° C. can be beneficial. However, to maintain the benefits of CFD, the temperature of the substrate measured in Kelvin, divided by the average temperature of the supercritical solution measured in Kelvin, may typically be maintained between 0.8 and 1.7.

In some cases, the supercritical fluid can participate in the reaction. For example, in a supercritical solution including N₂O as a solvent and metal precursors such as organometallic compounds, N₂O can serve as an oxidizing agent for the metal precursors yielding metal oxides as the desired material. In most cases, however, the solvent in the supercritical fluid is chemically inert.

### System and Process for Deposition

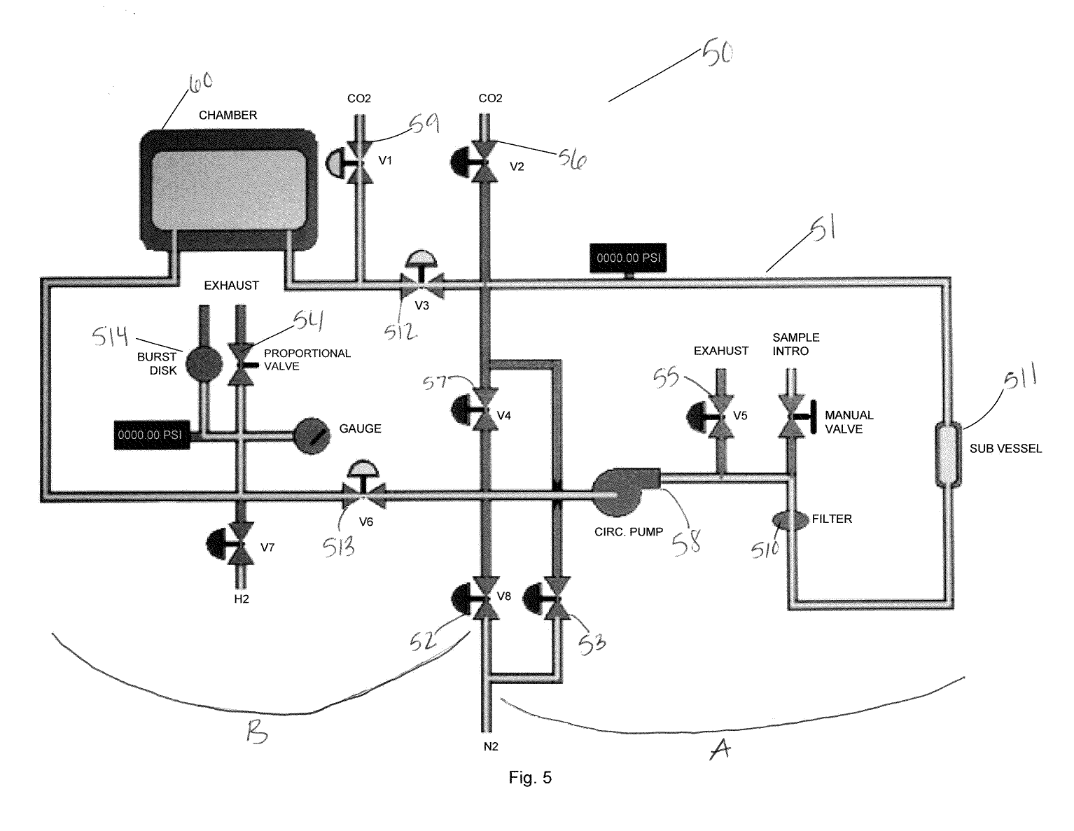

Looking now at FIG. 5, there is illustrated, in accordance with one embodiment of the present invention, a system 50 for implementing a CFD deposition protocol, for example, a supercritical fluid deposition protocol.

System 50, as shown, includes a pathway 51 along which a supercritical gas, a precursor material, and/or a reagent may be directed individually from its respective source, as part of a supercritical fluid mixture, or both. The system 50 also includes a reactor 60, within which a plurality or batch of substrates to be coated with a conformal thin film may be positioned. It should be noted that since many of the intended materials to be deposited, such as metals and other precursors, have substantially low vapor pressure and may be solid in nature, it may be difficult to dissolve them substantially for use in a supercritical CO₂ deposition process at low temperatures, i.e., below 100° C. To that end, system 50, in an embodiment, may be designed to facilitate and enhance the dissolving of a precursor material in solution, while minimizing occurrences of its precipitation from solution for subsequent conformal thin film deposition.

To initiate the deposition process, in accordance with one embodiment of the present invention, system 50 may initially be purged to flush away any residual reactants, byproducts, or other particulates or materials that may remain within pathway 51 and reactor 60 prior to actual deposition. In particular, an inert gas, such as N₂, may be introduced into pathway 51 using valves 52 and 53, directed around pathway 51, and allowed to exit through proportional valve 54 along with the residual reactants, byproducts and/or other materials.

Thereafter, a precursor material for subsequent deposition on to the surface of the substrates, including within the nanoscaled features, may be introduced into system 50. The precursor material, examples of which are provided above, may be provided in solid or liquid form, and may, in an embodiment, be slightly pressurized, for instance, by N₂ gas or any other appropriate gases. In one embodiment of the invention, the precursor material may be introduced into pathway 51 through the use of valve 55. To prevent the precursor material from leaving pathway 51, proportional valve 54 as well as valves 512 and 513 may be placed in a closed position. It should be appreciated that since the deposition process employed by the present invention involves the use of supercritical gases, such as CO₂, high pressure valves which can withstand pressures from the supercritical gases may be provided throughout pathway 51 and system 50.

Next, to generate the supercritical gas, a solvent, such as CO₂, may be supplied to a pump (not shown) adjacent valve 56 in either liquid form, or as a high-pressure gas. In the case the solvent is to be supplied as a gas, the solvent may subsequently be condensed to a liquid. Valves 56 and 57 may then be opened to introduce the solvent into pathway 51, whereby it may be pressurized to supercritical pressure. For CO₂, it is about 1100 PSI and can be higher. Upon introduction into the pathway 51, the solvent may be permitted to mix with the precursor material previously provided in the pathway 51 to provide a supercritical fluid mixture. It should be noted that whether the solvent is supplied as a gas or a liquid, a reaction agent, such as Hydrogen (e.g., H₂ gas) may also be introduced and allowed to mix with the supercritical fluid mixture containing the solvent and precursor to assist in the supercritical processing of the precursor for subsequent deposition. Once reaching supercritical pressure, valve 56 may be closed, and heat may be added to bring this supercritical fluid mixture up to supercritical temperature. In the case of supercritical CO₂, the temperature is about 31° C. At this supercritical condition, the mixture remains substantially stable and non-reactive, with the precursor material in a dissolved state in solution. However, this supercritical condition is at a temperature below a threshold temperature necessary to drive the reaction for thin film growth.

To facilitate and enhance the dissolving of the precursor material in solution (i.e., the supercritical fluid mixture), while minimizing occurrences of its precipitation therefrom, a recirculation pump 58, similar to that made by Micropump of Canada, may be placed along pathway 51. With valves 512 and 513 closed, pump 58, in an embodiment, can be employed to recirculate the supercritical fluid mixture through a filter 510 and a vessel 511, and along loop A (i.e., pre-circulation loop) of pathway 51. In one embodiment, pump 58 acts to impart turbulence to the flow of the supercritical fluid mixture within pathway 51, so as to facilitate solubility of the precursor material in solution.

In an embodiment, vessel 511 may be designed to represent, for example, about 10% of the volume of reactor 60. Of course, vessel 511 can be of a different relative volume should that be necessary. This vessel 511, in connection with loop A of pathway 51, can be utilized during recirculation of the supercritical fluid mixture to provide the necessary space within loop A where mixing of the precursor material within the supercritical fluid can occur to support a solubility limit required by reactor 60 for thin film deposition. In other words, vessel 511 may be used to permit adequate mixing therein, so as to satisfy the minimum precursor concentration within solution needed to promote sufficient thin film deposition once the supercritical fluid mixture is circulated through the entire pathway 51, including loop B, and into reactor 60. For example, if typically about 2%, by weight, of the precursor material can be dissolved within loop A in the presence of vessel 511, then about 0.2%, by weight, of the precursor material is available within the reactor 60 when the supercritical fluid mixture is circulated over the entire pathway 51. In general, about 0.2%, by weight, of the precursor material is what may be needed to provide sufficient conformal thin film deposition in the batch reactor 60. If, on the other hand, the vessel 511 were not used, then the precursor material may not be sufficiently dissolved by circulating only through loop A. Specifically, there may not be sufficient volume or space available within loop A to accommodate the necessary volume of supercritical fluid to permit dissolving of the necessary amount of precursor material. As such, the precursor concentration within the fluid mixture may be too low when the fluid mixture is circulated through the entire pathway 51, and thus within the entire volume of reactor 60, so as to permit sufficient film growth. It should be appreciated that solubility limits may not be practical much above 3 or 4% in reasonable temperatures and pressures of supercritical fluid.

As for filter 510, in an embodiment, it may be positioned downstream of pump 58. By placing filter 510 downstream of pump 58, filter 510 may be used not only to keep the recirculation loop A and/or loop B of pathway 51 clean of particulate, but may also be used to maintain the precursor material in a place of high turbulence and restricted flow path in order to facilitate solubility. If filter 510 were not provided, much of the precursor material may not dissolve in a reasonable time or may be lost altogether. In one embodiment, a reasonable time period for allowing the precursor material to be substantially soluble in the supercritical fluid mixture may be from about 10 minutes to about 60 minutes.

Although supercritical fluids can exhibit relatively high Reynolds number and low viscosity, such may not necessarily prevent the formation of stagnant zones within the reactor 60. It has been observed that, in certain instances, there exist areas of higher deposition than other areas. Moreover, convection can also occur within existing commercially available reactors, which, more often than not, can prevent uniform conformal deposition. With a batch reactor, the likelihood of non-uniform deposition can only increase due to convection or stagnation as the chemical reaction continues during the deposition process. For these reasons, recirculation pump 58 may be included in pathway 51 to uniformly distribute and mix the supercritical fluid mixture throughout system 50, and to permit the dissolved precursor material therein to substantially reach reactor 60 in a reasonable amount of time (e.g. 10 minutes or an hour). Without recirculation protocol as provided, substantially uniform batch reaction and conformal deposition using supercritical gas may be inhibited.

Moreover, it should be appreciated that in typical hot wall reactors, such as those employing a CVD process, essentially all surfaces of the reactor can have thin films deposited thereon. For a single substrate reactor, the consumption of the precursor material by the surfaces of the reactor itself may be significant relative to the deposited on to the surface of the substrate. As an example, typical CVD processes in a single substrate reactor often waste about 90% of the precursor material. However, because of the design of the batch reactor 60 of the present invention, only a small fraction of the precursor material may be consumed by deposition on the walls, making it much more economical to deposit precious metals etc. on to a batch of substrates using system 50 of the present invention. In an embodiment, the amount of precursor material consumed by the walls of batch reactor 60 may only about 4% when accounting for total surfaces, including substrate surfaces.

Looking again at FIG. 5, while the supercritical fluid mixture is being recirculated by pump 58 through loop A of pathway 51 to enhance dissolving of the precursor material, a batch of substrates to be coated may be loaded into the batch reactor 60, and the reactor 60 may thereafter be closed. Next, a reagent gas, such as H₂ may be introduced into reactor 60 through valve 59, so as to pressurize reactor 60 to a sufficient level in order to subsequently run the necessary reaction for thin film deposition. If necessary, proportional valve 54 may be used to control and regulate the pressure.

To the extent desired, prior to the introduction of the supercritical fluid mixture, the batch reactor 60 may also be conditioned to the temperature of the supercritical fluid mixture, so as to minimize shock and preserve the supercritical condition for the deposition process. In this example, since about 1100 PSI is employed in connection with CO₂, reactor 60 may be maintained at about 31° C. to preserve the supercritical condition. Moreover, in an embodiment, pressure gauges, such as gauge 513, and metal burst discs, such as disc 514, may be provided to monitor and maintain the safety of the system 50.

Thereafter, with valves 512 and 513 opened and valve 54 closed, the supercritical fluid mixture of supercritical gas and substantially dissolved precursor material may be directed along loop B of pathway 51 into reactor 60. Upon being directed toward reactor 60, the supercritical fluid mixture, including the substantially dissolved precursor, moves to a less than saturated condition, for example, about 0.2% by weight, and continues to be recirculated throughout the system 50 to maintain the dissolved precursor material in solution. The system 50, along with reactor 60 may then be rapidly heated from about 31° C. to above a threshold reaction temperature necessary to drive the reaction for thin film deposition onto the substrates. By bringing the temperature around which the batch of substrates sit within the reactor 60 to above the threshold reaction temperature, the temperature of the batch of substrates can similarly be raised to the threshold level. In the case where the precursor is, for example, Platinum, the threshold reaction temperature may be in the range of from about 40° C. to about 60° C. To the extent that other precursors may be used, the temperature may be varied accordingly up to about 400° C. In accordance with an embodiment, the time frame during which the substrates may be heated to the threshold reaction temperature may range between about 1 second to about 600 seconds. In one embodiment, the time frame can be between about 20 seconds to about 120 seconds.

It should be appreciated that since, for example, Hydrogen assisted SCCO₂ deposition rates may be zero order dependent on concentration, the temperature may be used accurately control the deposition process, so long a the concentration of the precursor material is maintained above a certain level. Accordingly, to stop the deposition or growth process or when a desired thin film thickness has been reached, the temperature of the substrates within reactor 60 may be lowered, such as by heat radiation or conduction, to that below the threshold reaction temperature. In an embodiment, the time frame during which the substrates may be cooled below the threshold reaction temperature may range between about 60 seconds to about 600 seconds. In one embodiment, the time frame can be less than about 120 seconds.

After deposition has reached a desired thickness on the substrate, proportional valve 54 may be opened, so that substantially all the gases (e.g., SCCO₂, H₂) and solutes (e.g., precursor ligands, unused precursor) can leave the system 50. To facilitate removal of residual gases and solutes from the reactor 50 and pathway 51, additional amounts of a supercritical gas, such as SCCO₂, may be used to flush the system 50, since there is substantially good solubility with the residual gases and the solutes. In one embodiment, a cleaning additive may be used with the supercritical gas to enhance the flushing and cleaning process. A by-product trap, such as an activated carbon canister, may also be provided for use in connection with the cleaning process.

Once the first layer has been deposited onto the surface of the substrate, including within the nanoscaled features, subsequent thin film layers may be sequentially deposited atop the first layer on the substrate by repeating the process and steps disclosed above.

Once the deposition process has completed, reactor 50 may be allowed to depressurize toward a transfer pressure. The transfer pressure may be positive or negative (vacuum) depending on the situation. Transfer pressure, in one embodiment, can be achieved through the use of a downstream pressure controller or the use of a connected vent line to the handler (not shown).

It should be appreciated that although described as above, the deposition protocol, in one embodiment, may be modified so that prior to introducing the mixture of supercritical gas and precursor material that has been circulating in loop A into reactor 60, the batch of substrates to be coated may be heated within reactor 60 to above the threshold temperature necessary for film growth to be initiated on the surface of each substrate. With such an approach, in order to minimize shock and to preserve the necessary condition (i.e., minimizing precipitation or loss of solubility of the precursor material in solution) for thin film growth within reactor 60, the mixture of supercritical gas and precursor material may be heated, within loop A, to similar temperature level as that of the heated batch of substrates. In addition, the remainder of pathway 51, including loop B, may also be heated to a similar temperature level to preserve the necessary condition as the mixture travels to reactor 60. Thereafter, the mixture may be introduced into reactor 60, so as to permit deposition of a substantially conformal thin film on to the surface and along the nanoscaled feature of the substrate. To stop the deposition or growth process or when a desired thin film thickness has been reached, the temperature of the substrates within reactor 60 may be lowered to that below the threshold reaction temperature.

### Batch Reactor

To continue at the present pace of miniaturization of electronic components, the micro- and nano-electronics sectors are substantially dependent on the ability to deposit thin films, such as metals, metal oxides, and organic compounds into ever smaller spaces. To address that need, the present invention provides a batch reactor that can be used in connection with the system 50, disclosed above, deposition to permit deposition protocols to be carried out quickly, efficiently, and cost effectively.

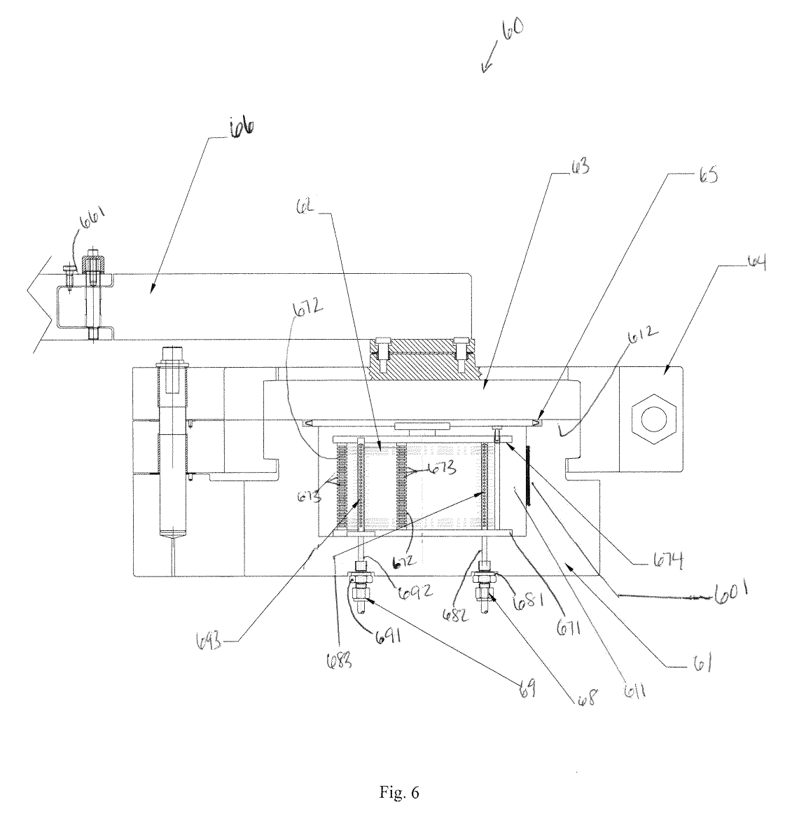

Referring now to FIG. 6, there is illustrated a cross-sectional view of a batch reactor 60 that may be used in connection with the supercritical fluid system 50 to permit simultaneous conformal thin film deposition of a plurality of substrates in a quick, efficient and cost effective manner. The reactor 60, in one embodiment, includes a body portion 61 having a chamber 611 within which a batch of substrates 62 may be positioned for simultaneous thin film deposition. The reactor 60 may also include a lid portion 63 designed to complementarily engage the body portion 61, so as to provide a substantially airtight fit with chamber 611. To allow the lid portion 63 to remain engaged with the body portion 61 during deposition, clamps 64 may be provided to substantially lock the lid portion 63 in position, so as to prevent any accidental opening that may be caused by the high pressure level within chamber 611 of reactor 60 during deposition.

To enhance the security of the fit between the lid portion 63 and the body portion 61, and to minimize leakage of gases from within the chamber 611 during deposition, a seal 65 may be provided about an upper rim 612 of the body portion 61. In one embodiment, seal 65 may be a commercially available “v” Teflon seal. The presence of seal 65 at such a location allows it to engage the lid portion 63 and to seal off any opening that may exist between the lid portion 63 and the upper rim 612 of the body portion 61. In one embodiment, seal 65 may be designed to inflate by the pressure within the reactor 60 to further enhance the tight fitting engagement between the lid portion 63 and the body portion 61.

As the batch reactor 60 may need to be sufficiently large to accommodate the large number of substrates 62 within the chamber 611 of body portion 61, reactor 60 may also be provided with a lift arm 66 to assist in the opening of the lid portion 63. In an embodiment, one end of the lift arm 66 may be coupled to the lid portion 63, while an opposite end may be coupled to a pivot point 661. It should be appreciated that any coupling mechanisms known in the art, for instance, screws, bolts, welding etc., may be used to connect the lift arm 66 to the lid portion 63. Moreover, pivot point 661 may be designed to either allow the lift arm 66 to pivot up and lift the lid portion 63 off of the body portion 61, or allow the lift arm 66 to rotate along a plane substantially perpendicular to the sheet of paper illustrating FIG. 6, so as to slide the lid portion 63 off the body portion 61. To assist in the removal of the lid portion 63, a stepper motor or other mechanized devices may be utilized in connection with lift arm 66.

Still referring to FIG. 6, batch reactor 60 may also include a cassette 67 designed to be received within chamber 611 of body portion 61 and for accommodating a plurality or batch of substrates 62. Cassette 67, in an embodiment, may include a base 671, and sufficiently spaced columns 672 positioned on base 671. Each of columns 672, as illustrated, may be provided with a series of shelves 673 placed axially along the column 672. In an embodiment, the axially placed shelves 673 along one column 672 may be provided at substantially the same height as the shelves 672 on an adjacent column 672. In this way, for example, one end of a substrate 62 may be placed on one shelf 673 of one column 672 and an opposite end of that substrate 62 may be placed on another shelf 673 at substantially the same height level on that other column 672. With such a design, a plurality of substrates 62 may be stacked atop one another in axial alignment in the manner shown in FIG. 6. It should be appreciated that shelves 673 may be sufficiently spaced along each column 671, so that when the substrates 62 are stacked in cassette 67, there may be a gap provided between each substrate 62. By providing a gap between each substrate 62, the supercritical fluid mixture may be permitted to flow between adjacently stacked substrates 62, so that a conformal thin film may be formed on the surface of each substrate 62, including within the nanoscaled features. To retain the substrates 62 within cassette 67 and to prevent them from falling out during handling, cassette 67 may be provided with a retainer 674 which can be secured across a top end of columns 672. It should be noted that although cassette 67 is provided, other designs may be utilized to accommodate a plurality of substrates for simultaneous thin film deposition. Alternatively, a plurality of substrates 62 may be flatly positioned on a tray (not shown) for simultaneous thin film deposition.

To introduce the supercritical fluid mixture from pathway 51 of system 50 into the reactor 60, inlet 68 may be provided on body portion 61 of reactor 60, so that a passageway may exist for directing the supercritical fluid mixture into chamber 61. Inlet 68, in an embodiment, may include a seal 681, such as an O-ring seal, to permit substantially air-tight engagement with pathway 51 and minimize any leakage of the supercritical fluid mixture as it gets directed from pathway 51 into reactor 60. To ensure that the supercritical fluid mixture is sufficiently introduced to the batch of substrate within chamber 611, inlet 68 may also include an inlet manifold 682 extending across the body portion 61 and into chamber 611 of reactor 60. As illustrated, inlet manifold 682 may include a plurality of apertures 683 through which the supercritical fluid mixture may enter into chamber 611. In one embodiment, apertures 683 may be placed axially along inlet manifold 682, and may be sufficiently spaced so that each aperture 683 can distribute a stream of supercritical fluid mixture into the gap between adjacently stacked substrates 62. In addition to fluid distribution, inlet manifold 682 can be used to force convection of heated supercritical fluid mixture and/or supercritical gas into chamber 611 and across the surfaces of substrates 62. To the extent that fluid flow within chamber 611 may become stagnant or not well distributed, inlet manifold 682 can act to mix or create turbulent flow within chamber 611 by introducing additional supercritical fluid mixture into the chamber 611. The introduction of turbulent flow or mixing can provide a substantially more even and/or uniform distribution of flow within chamber 611.

To allow the supercritical fluid mixture to exit chamber 611 and recirculate along pathway 51, reactor 60 may be provided with outlet 69 in fluid communication with outlet manifold 692. Outlet manifold 692, similar to inlet manifold 682, includes a plurality of apertures 693 through which the supercritical fluid mixture may exit from chamber 611. Apertures 693, in an embodiment, may be placed axially along outlet manifold 692 and may be sufficiently spaced in a manner similar that of apertures 683. It should be appreciated that the presence of apertures 693 and outlet manifold 692 can act to enhance the mixing or creation of turbulent flow by interfering with the flow within chamber 611. To minimize the occurrence of leakage of supercritical fluid mixture or other supercritical gases when they get directed from within chamber 611 into pathway 51 for recirculation, outlet 69 may include a seal 691, such as an O-ring seal, to permit substantially air-tight engagement with pathway 51. It should be noted that although outlet 69 and outlet manifold 692 may be described as mechanisms to permit removal of the supercritical fluid mixture from chamber 611, they can very well function as an inlet and inlet manifold respectively. In particular, if the flow of fluid along pathway 51 were to be reversed, outlet 69 and outlet manifold 692 can act as inlet mechanisms in a similar manner to inlet 68 and inlet manifold 682, while inlet 68 and inlet manifold 682 can act as outlet mechanisms.

To generate the necessary amount of heat within chamber 611 and for the batch of substrates 62, that is, the necessary temperature to maintain supercritical conditions or to drive the growth of conformal thin film layers, reactor 60 may be provided with at least one heating element 601. However, in order to facilitate to the heating process, reactor 60 may be provided with a plurality of heating elements 601, each along one side of reactor 60. Although illustrated as being on the outside of reactor 60, heating elements 601 may be situated within the walls of reactor 60 or within chamber 611. To the extent desired, additional heating elements 601 may be provided on clamps 64 or other components of the batch reactor 60. In one embodiment, the heating elements 601 provided may be commercially available heating elements designed to permit the temperature of within chamber 611 to be elevated to a temperature range of from about 20° C. to about 400° C., or other desired temperature ranges. In addition to being located on reactor 60, it should be appreciated that heating elements 601 may also be provided along pathway 51 and on recirculation pump 58 to maintain the supercritical fluid mixture at supercritical temperature as the mixture is being circulated along pathway 51 during the deposition process.

In order to supply the necessary energy to activate the heating elements 601, reactor 60 may include an electrical line (not shown) connecting to each of the heating elements 601. Furthermore, to elevate or decrease the temperature of the heating elements 601 in a precise and controlled manner, a control module (not shown) may be provided. In one embodiment, the control module may act to elevate the temperature of the heating elements 601 at a rate of, for instance, 1° per minute. Of course, the control module can be designed to elevate the temperature of the heating elements 601 at any rate desired. In an embodiment, the time frame during which the heating elements 601 may increase the temperature of the substrates to the threshold reaction temperature may range between about 1 second to about 600 seconds. In one embodiment, the time frame can be between about 20 seconds to about 120 seconds.

To prevent the heating elements 601 from being elevated to that beyond a desired level, reactor 60 may include a feedback controller 602, such as a thermocouple device, connected to the heating elements 601 and in communication with the control module, so that if necessary, the energy supplied to the heating elements 601 can be reduced or cut off. In an embodiment, the time frame over which the temperature of the substrates may decrease, for example, through heat radiation or conduction, to below the threshold reaction temperature may range between about 60 seconds to about 600 seconds. In one embodiment, the time frame can be less than about 120 seconds.

### Fabrication of Coated Substrates

A plurality of conformal thin film substrates may be fabricated simultaneously, for economy of scale, in accordance with an embodiment of the present invention. These substrates may be utilized for various applications, including as capacitors, interconnects, conductive channels, cantilever beams, among others.

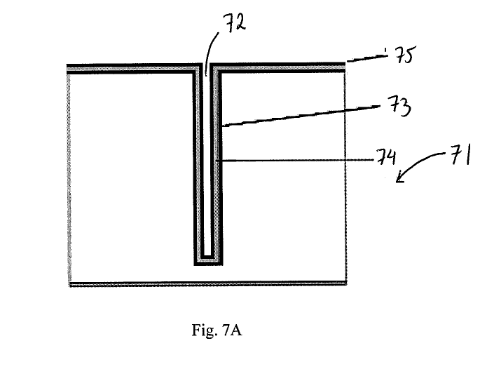

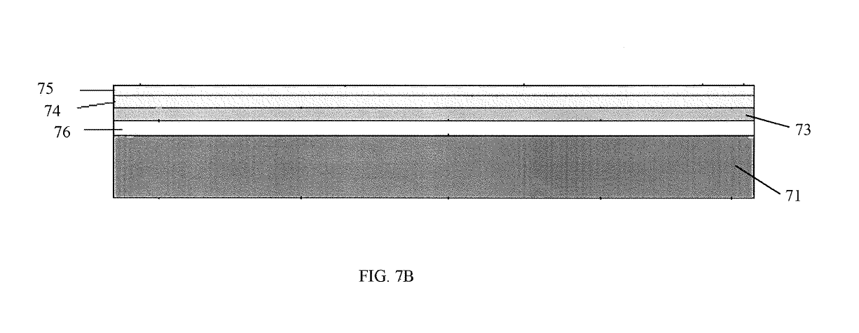

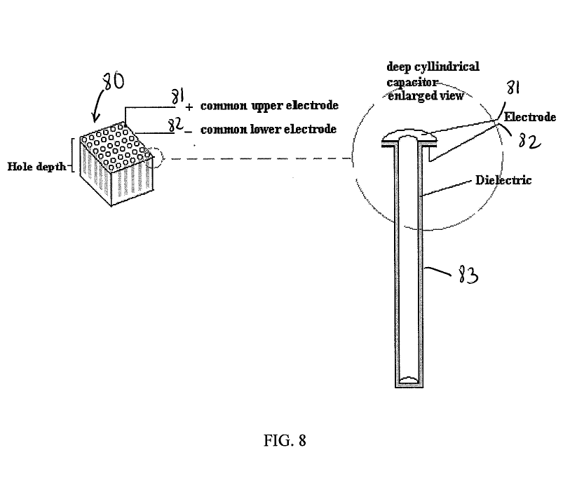

Looking now at FIG. 7A, there is illustrated a coated substrate 71 in accordance with an embodiment of the present invention. For ease of discussion, reference is made below to one substrate. However, it should be appreciated that the process and system of the present invention can be utilized to coat a plurality or batch of substrates simultaneously for economy of scale.

To fabricate coated substrate 71, a Silicon substrate, such as that shown in FIG. 7A, having at least one nanoscaled feature 72 of substantially high aspect ratio of depth to width may initially be provided. Of course, a substrate having any desired characteristics or made from any material may be used. Next, a layer 73 may be provided by depositing a conformal thin metal film onto the surface of substrate 71, including along all exposed surfaces within nanoscaled feature 72, using Hydrogen assisted SCCO₂ deposition of a precursor material, such as an organic precursor, a metallo-organic precursor, or one of the precursors disclosed above, for instance, Cu, Ru, Ni, Ir, Pt, Rh, Al, Ag, Au, Pd, Cu, AlCu, AlCuSi, etc. This thin metal film layer 73 may thereafter, in an embodiment, be oxidized in O₂ at a temperature ranging from about 300° C. to about 1100° C. depending on the precursor used to form this layer. If this thin metal layer 73 is to function, for instance, as a high k dielectric, then the precursor material used may be a metal oxide, including, for instance, SrTa, Hf, Ta, Al, or HfSi. Of course, other related metals or metal alloys, such as Pb, Zr, Ti, BiLaTi, SrTaNiNb, SrTaBi, BiTi, PbZrTi or SrTi, or a combination thereof may be used. It should be noted that the layer 73 can be provided with adhesive characteristics, compatible grain size, and compatible thermal expansion to that of any subsequent layers that may be deposited thereon.

In coating the high aspect ratio substrate 71, it should be appreciated that the total thickness of the metal film layers thereon, in an embodiment, may range from about 50 Angstroms to about 5000 Angstroms or more on the substrate 71. In an embodiment, the first or starting layer 73 on the surface of substrate 71 may be provided with a thickness ranging from about 10 Angstroms to about 1000 Angstroms. Subsequent layers may also be provided with a similar or different thickness range, depending on the materials. For instance, the thickness range may be from about 50 to about 500 Angstroms for layer 73, and from about 500 to about 5000 Angstroms for subsequent layers. It should be noted that in the Hydrogen assisted SCCO₂ process employed herein, the desired thickness for the first thin layer 73 can be achieved relatively quickly, for instance, in about a minute or less.

After the first conformal thin metal layer 73 has been deposited, a second conformal thin metal film layer 74 can be deposited atop the first thin metal layer 73. Layer 74 can be formed by using a similar precursor metal, a different precursor metal. In an embodiment the precursor material may be one whose oxide is conductive, examples of which include, Cu, Ru, Ni, Ir, Pt, Rh, Al, Ag, Au, Pd, Cu, AlCu, AlCuSi, etc. The second thin metal film layer 74 may subsequently be oxidized in O₂ at a temperature ranging from about 300° C. to about 600° C. depending on the precursor used. In the case of Ru and Ir for instance, the oxidation process can provide the a layer 74 with a conductive oxide which can also act as a gas barrier. The oxidation process can also provide the layer 74 with adhesion characteristics, compatible or desired grain size, and compatible thermal expansion, among others, similar to that of the first layer 73.

It should be noted that if layer 74 is composed of a noble metal, then no oxidation takes place, but the layer can permit oxygen to permeate therethrough to oxidize the other layers.

In an alternate embodiment, the first thin metal film layer 73 and the second thin metal film layer 74 can initially be deposited in sequence. Thereafter, a single oxidation step in O₂, can be performed to simultaneously oxidize the first thin metal film layer 73 and the second thin metal film layer 74. Although described in connection with the Hydrogen assisted SCCO₂ deposition process, it should be noted that the deposition of the film layers may be carried out with or without the Hydrogen assisted SCCO₂ deposition process.

In another embodiment, a barrier layer 75 may be deposited atop the thin film layer 74 to protect layer 74 against oxide reduction, for instance, due to subsequent interconnect processing. In particular, a precursor metal or alloy, or one whose oxide can act as a barrier to a gas (e.g., Hydrogen or Oxygen), or a barrier to a semiconductor contaminant element, such as Na, Ca, or Ru, may be used to form a third thin film barrier layer 75. Examples of such metal, alloy or oxides thereof include Ru, Ir, Al, Cu, Pd, Au, Ag, Pt, Ni or a combination thereof. Once deposited, this barrier thin metal film layer 75 may subsequently be oxidized in O₂ at a temperature ranging from about 300° C. to about 600° C., depending on the precursor used. The oxidation process can also provide the thin film barrier layer 75 with adhesion characteristics, compatible grain size, and compatible thermal expansion to that of the other layers. Moreover, although described in connection with the Hydrogen assisted SCCO₂ deposition process, it should be noted that the deposition of the thin film barrier layer 75 may be carried out with or without the Hydrogen assisted SCCO₂ deposition process. In addition, if desired, a similar barrier layer may be deposited between first thin film layer 73 and second thin film layer 74.

To the extent desired, with reference now to FIG. 7B, it may be advantageous to utilize an adhesion layer 76 to enhance adhesion of first thin film layer 73 to substrate 71. In such instances, adhesion layer 76 may be deposited on substrate 71 prior to the application of first thin film layer 73 atop adhesion layer 76. In one embodiment, adhesion layer 76 may be a metal oxide adhesion layer, for instance, one formed from Titanium oxide.

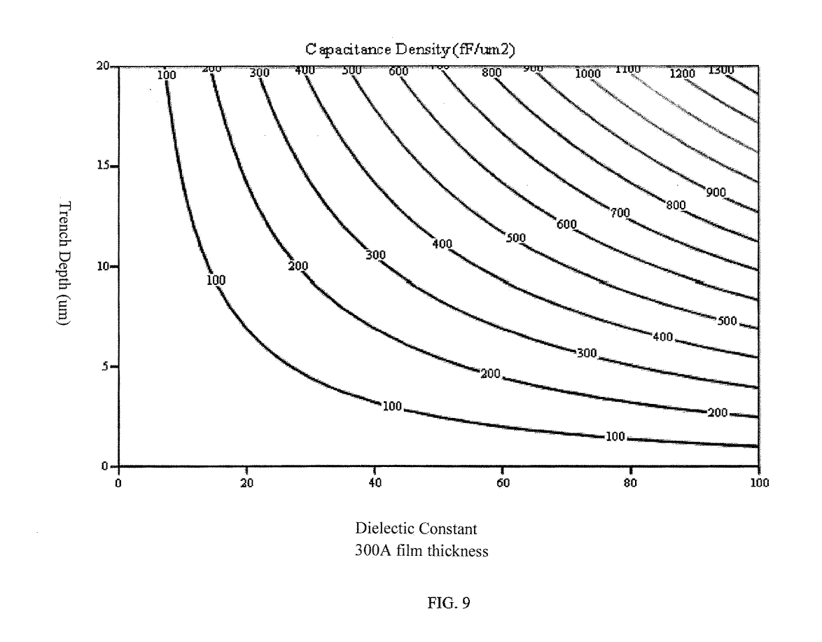

It should be appreciated that a three dimensional (3-D) substrate may coated to fabricate, for instance, a capacitor or capacitor array 80, such as that shown in FIG. 8 using the Hydrogen assisted SCCO₂ deposition process employed by the present invention. The array 80, in one embodiment, may be provided with a common top electrode 81 and a common bottom electrode 82 rather than individual top and bottom electrodes for each capacitor 83 in the array 80. With such a 3-D array, capacitor 80 can exhibit, in one embodiment, an increase in capacitance density up to about 150 times (see FIG. 9). Alternatively, capacitor array 50 may be made approximately 150 times smaller than current high k designs, while maintaining similar capacitance density to that of current designs. Such characteristics can easily provide a solution to IC chip isolation problem and enable implementation of higher-speed logic, microprocessor, mobile and memory LSI circuits, among others.

The resulting capacitor structure for integrated circuits (Decoupling, Tuning, DRAM, ROM, SRAM, FeRAM etc.) may, in one embodiment, be provided with high aspect ratio feature over 5:1, e.g., ranging from at about 5:1 to about 100:1 depth to width, and may include conformally deposited thin layers, including a high k dielectric layer, that are substantially pure in content.

It should be appreciated that the conformal thin film deposited by the process of the present invention can be used to coat within nanoscaled or deep features of a substrate, for instance, those features for in connection with capacitors, interconnects, conductive channels, cantilever beams etc.

The process of the present invention can also be used to coat within nanoscaled or very small channels of substrates that may be used as a catalytic converter, similar to those utilized in automobile exhaust systems. Such a converter may, for instance, include a ceramic substrate with numerous nanoscaled or very small channels coated with a Platinum/Rhodium thin film. Other substrates with small channels for use in any other applications may also be coated with the process of the present invention.

The foregoing has outlined, in general, certain aspect of the invention and is to serve as an aid to better understanding the more complete detailed description which is to follow. In reference to such, there is to be a clear understanding that the present invention is not limited to the method or detail of construction, fabrication, material, or application of use described and illustrated herein.

Moreover, while the invention has been described with reference to particular embodiments, it will be understood by those skilled in the art that various changes may be made and equivalents may be substituted for elements thereof without departing from the scope of the invention. In addition, many modifications may be made to adapt a particular situation or material to the teachings of the invention without departing from the scope of the invention.

What is claimed is:

1. A method for coating a batch of substrates, the method comprising:
providing, within a controlled environment, a plurality of substrates, each having at least one nanoscaled feature extending into the substrate;
introducing, into the controlled environment, a mixture of a supercritical gas and a precursor material in a manner which minimizes precipitation or loss of solubility of the precursor material in the mixture;
heating the substrates simultaneously, in the presence of the mixture, to above threshold temperature at which film growth can be enabled;
permitting deposition of a substantially conformal thin film on to the surface and along the nanoscaled feature of the substrates; and
cooling the substrates to temperature at which film growth can be terminated upon reaching a predetermined thickness.

2. A method as set forth in claim 1, wherein, in the step of providing, the nanoscaled feature includes a trench extending into the substrate from the surface of the substrate.

3. A method as set forth in claim 1, wherein, in the step of providing, the substrate includes a relatively high aspect ratio feature ranging from about 5:1 to about 100:1 depth to width.

4. A method as set forth in claim 1, wherein, in the step of heating, the threshold temperature can be about 400° C. or less.

5. A method as set forth in claim 1, wherein, in the step of heating, the threshold temperature can be established by a temperature gradient in range of from about 40° C. to about 250° C. between that of the substrates and that of the supercritical fluid mixture.

6. A method as set forth in claim 1, wherein the step of introducing includes recirculating the mixture to enhance solubility of the precursor material within the mixture.

7. A method as set forth in claim 1, wherein the step of introducing includes recirculating the mixture to maintain a necessary concentration level of the precursor material to permit sufficient thin film growth within the controlled environment.

8. A method as set forth in claim 7, wherein, in the step of recirculating, the concentration of the precursor material within the controlled environment is approximately 0.2% by weight.

9. A method as set forth in claim 7, wherein the step of recirculating includes filtering unwanted particulates from the mixture flow, so that a substantially conformal and uniform thin film can subsequently be deposited on to the substrates.

10. A method as set forth in claim 1, wherein, in the step of exposing, the deposition occurs over a period of about ten minutes or less until a desired thin film thickness is achieved.

11. A method as set forth in claim 1, wherein, in the step of cooling, a time frame during which the substrates can be cooled below the threshold temperature ranges from about 1 second to about 600 seconds.

12. A method as set forth in claim 1, further including:
introducing, into the controlled environment, a second mixture of a supercritical gas and a second precursor material in a manner which minimizes precipitation. or loss of solubility of the second precursor material in the mixture;
exposing the substrates to the second mixture, so as to permit deposition of a second substantially conformal thin film on top of the initial thin film on the surface and along the nanoscaled feature of the substrate.

13. A system for coating a batch of substrate, the system comprising:
a pathway along which a mixture of a supercritical gas and a precursor material can be directed, the pathway having a pre-reaction loop;
a reactor, in fluid communication with the pathway, and within which a batch of substrates can be placed for thin film deposition;
a pump for recirculating the supercritical fluid mixture along the pathway, so as to facilitate and enhance solubility of the precursor material in the mixture; and
a vessel in fluid communication with the pre-reaction loop of the pathway to provide additional volume within which the supercritical gas and precursor material can sufficiently mix to satisfy a minimum precursor concentration within solution in order to promote sufficient thin film deposition once the supercritical fluid mixture is circulated into the reactor.

14. A system as set forth in claim 13, wherein the pre-reaction loop can be closed off from the remainder of the pathway prior to thin film deposition in order to provide a route through which the precursor material and the supercritical gas can mix to generate the minimum precursor concentration needed for thin film deposition when introduced into the reactor.

15. A system as set forth in claim 13, wherein the reactor includes an inlet through which the supercritical fluid mixture can be introduced into the reactor for thin film deposition and an outlet through which the supercritical fluid mixture can exit from the reactor for recirculation through the pathway in order to maintain the necessary precursor concentration within solution.

16. A system as set forth in claim 13, wherein the pump acts to impart turbulence to the flow of supercritical fluid mixture so as to facilitate solubility of the precursor material in mixture.

17. A system as set forth in claim 13, wherein the vessel has a volume that is about 10% of the volume of the reactor.

18. A system as set forth in claim 13, further including a filter positioned within the pathway downstream of the pump to keep the pathway substantially clear of particulate.

19. A system as set forth in claim 18, wherein the filter further acts to maintain the precursor material in a place of substantial high turbulence in order to facilitate solubility.

20. A coated substrate comprising:
a substrate having at least one nanoscaled feature of substantially high aspect of ratio of depth to width;
a conformal thin film layer having a mixture of a supercritical gas and a precursor material deposited substantial uniformly across a surface of the substrate and along all exposed surfaces of the nanoscaled feature; and
a conformal barrier layer deposited atop the thin film layer to protect the thin film layer against oxide reduction.

21. A coated substrate as set forth in claim 20, wherein the substrate includes a Silicon material.

22. A coated substrate as set forth in claim 20, wherein the high aspect ratio feature ranges from about 5:1 to about 100:1 depth to width.

23. A coated substrate as set forth in claim 20, wherein the supercritical gas includes one of O₂, C₂H₆, C₃H₈, CH₃—O—CH₃, and CH₃CH₂OH.

24. A coated substrate as set forth in claim 20, wherein the precursor material includes one of Cu, Ru, Ni, Ir, Pt, Rh, Ta, Hf, Al, Ag, Au, Pd, Ti, Cu, Zr, Pb, BiLaTi, SrTaNiNb, SrTaBi, SrTa, AlCu, AlCuSi, BiTi, PbZrTi, SrTi, HfSi or a combination thereof.

25. A coated substrate as set forth in claim 20, wherein the barrier layer includes one of Ru, Ir, Al, Cu, Pd, Au, Ag, Pt, Ni.

26. A coated substrate as set forth in claim 20, further including a second conformal thin film layer having a mixture of a supercritical gas and a second precursor material deposited substantial uniformly atop the initial conformal thin film layer and within the nanoscaled feature.

27. A coated substrate as set forth in claim 26, wherein the second precursor material includes one of Cu, Ru, Ni, Ir, Pt, Rh, Ta, Hf, Al, Ag, Au, Pd, Ti, Cu, Zr, Pb, BiLaTi, SrTaNiNb, SrTaBi, SrTa, AlCu, AlCuSi, BiTi, PbZrTi, SrTi, HfSi or a combination thereof.

28. A reactor for supercritical fluid deposition, the reactor comprising:
a body portion within which a batch of substrates can be positioned for simultaneous thin film deposition;
a lid portion for complementarily engaging the body portion, so as to provide a substantially airtight fit therewith in the presence of supercritical pressure;
a cassette for placement within the body portion and for accommodating a batch of substrates;
an inlet to introduce a supercritical fluid mixture into the reactor for subsequent thin film deposition on to a surface of each substrate in the batch; and
a heating element coupled to the body portion for raising temperature of the batch of substrates to a threshold temperature at which film growth can be enabled on the surface of each substrate.

29. A reactor as set forth in claim 28, wherein the body portion includes a chamber for accommodating the cassette and the batch of substrates.

30. A reactor as set forth in claim 28, wherein the body portion includes a seal about its upper rim to minimize leakage of gases from within the body portion during deposition.

31. A reactor as set forth in claim 28, wherein the cassette permits a plurality of substrates to be stacked in axial alignment, while providing a space between adjacently stacked substrates to permit the supercritical fluid mixture to flow therebetween, so that a conformal thin film may be formed on the surface of each substrate.

32. A reactor as set forth in claim 28, wherein the heating element can elevate the temperature of the substrates within the body portion to a threshold reaction temperature for thin film deposition over a period ranging from about 1 second to about 600 seconds.

33. A reactor as set forth in claim 28, wherein the body portion can be designed to lower temperature of the substrates through heat radiation or conduction to below a threshold reaction temperature for thin film deposition over a period ranging from about 60 seconds to about 600 seconds.

34. A method for coating a batch of substrates, the method comprising:
providing, within a controlled environment, a plurality of substrates, each having at least one nanoscaled feature extending into the substrate;
generating a mixture of a supercritical gas, a precursor material and a reagent gas;
adjusting a concentration of the precursor material in the mixture to a level that ensures sufficient thin film deposition of the substrates upon introduction of the mixture into the controlled environment;
rapidly increasing temperature of the substrates simultaneously, in the presence of the mixture, to above threshold temperature at which film growth can be enabled, in order to initiate thin film deposition on the substrate and along the nanoscaled feature; and
reducing the temperature of the substrates to below the threshold temperature in order to terminate thin film deposition upon reaching a predetermined thickness.

35. A method as set forth in claim 34, wherein, in the step of adjusting, the concentration of the precursor material upon introduction into the controlled environment is approximately 0.2% by weight.

36. A method as set forth in claim 34, wherein, in the step of rapidly increasing, the deposition occurs over a period of about ten minutes or less until a desired thin film thickness is achieved.

37. A method as set forth in claim 34, wherein the in the step of rapidly increasing, a time frame over which the substrates can be heated to above the threshold temperature ranges from about 1 second to about 600 seconds.

37. A method as set forth in claim 1, wherein, in the step of reducing, a time frame during which the substrates can be cooled below the threshold temperature ranges from about 60 seconds to about 600 seconds.
